(19) United States
(12) Patent Application Publication
(10) Pub. No.: US 2026/0282777 A1
(43) Pub. Date: Sep. 17, 2026

(54) METHOD FOR MANUFACTURING SEMICONDUCTOR DEVICE

(71) Applicants: HPSP Co., Ltd., Hwaseong-si, Gyeonggi-do (KR); POSTECH Research and Business Development Foundation, Pohang-si, Gyeongsangbuk-do (KR)

(72) Inventor: Hyunsang HWANG, Daegu (KR)

(21) Appl. No.: 18/878,805

(22) PCT Filed: Jun. 23, 2023
(86) PCT No.: PCT/KR2023/008751

§ 371 Date: Dec. 24, 2024

(30) Foreign Application Priority Data
Jun. 24, 2022 (KR) 10-2022-0077404

(51) Int. Cl. H10P 14/60; H10D 64/01; H10P 14/40; H10P 14/692

(52) U.S. Cl. CPC H10P 14/6536; H10D 64/013; H10P 14/40; H10P 14/69215; H10P 14/69392

(57) ABSTRACT

The present specification relates to a method for manufacturing a semiconductor device. A method for manufacturing a semiconductor device, according to an embodiment, may include: a step of forming an insulating layer on a substrate; a step of performing a microwave heat treatment process; a step of forming a conductive layer on the insulating layer; and a step of performing a heat treatment process.

### FIELD

The present disclosure relates to a method for manufacturing a semiconductor device.

### DESCRIPTION OF RELATED ART

As a semiconductor is scaled down, a thickness of a gate insulating film becomes smaller than a limit thereof, which causes leakage current. To overcome such problem, a material (e.g., SiO₂) with an excellent insulating effect is widely used in a manufacturing process of a semiconductor device, and recently, a high-K (high-dielectric constant) material (e.g., HfO₂, HfSiₓ, and HfAlₓ) is also used together for an active layer. During a deposition process of such insulating material and high-K material, defects in a structure occur. Therefore, the defects are cured by a heat treatment process. Therefore, importance of heat treatment process technology is increasing along with a technological development in the semiconductor field.

However, when high-temperature heat treatment is performed during the manufacturing process of the semiconductor device, a likelihood of generating ionized interface charges and trap charges increases, which may lower reliability of the semiconductor device. In addition, when the high-temperature heat treatment is performed during the manufacturing process of the semiconductor device, thermal budget may increase. Therefore, an efficient and economical heat treatment process that may be applied during the manufacturing process of the semiconductor device needs to be developed.

Prior art (Korean Patent No. 10-0621776) discloses a method for performing an annealing process on an amorphous silicon film for a short period of time and simultaneously applying microwaves thereon. However, the prior art does not disclose a method that may compensate for disadvantages of the microwave heat treatment.

### DISCLOSURE

### Technical Purposes

The present disclosure is to provide a method for manufacturing a semiconductor device that may increase reliability and improve electrical characteristics of the semiconductor device via a complex heat treatment.

The purpose of the present disclosure is not limited to the above-mentioned purpose, and other purposes and advantages of the present disclosure, which are not mentioned, will be more clearly understood based on embodiments of the present disclosure as described below. In addition, the purposes and advantages of the present disclosure may be realized based on components and combinations thereof described in the Claims.

### Technical Solutions

A method for manufacturing a semiconductor device according to one embodiment may include forming an insulating layer on a substrate, performing a microwave heat treatment process, forming a conductive layer on the insulating layer, and performing a heat treatment process.

A method for manufacturing a semiconductor device according to one embodiment may include forming a first insulating layer on a substrate, performing a first microwave heat treatment process, forming a second insulating layer having a permittivity higher than a permittivity of the first insulating layer on the first insulating layer, performing a second microwave heat treatment process, forming a conductive layer on the second insulating layer, and performing a heat treatment process.

### Technical Effects

According to the embodiments, the defects may be healed with the low thermal budget because of the microwave heat treatment during the manufacturing process of the semiconductor device.

According to the embodiments, the interface charges and the fixed charges may be passivated without damaging the conductive layer at the relatively low temperature during the manufacturing process of the semiconductor device.

According to the embodiments, the densities of the interface charges and the fixed charges of the semiconductor device may be reduced, thereby securing the excellent charge mobility characteristics.

According to the embodiments, the interface charges and the fixed charges may be passivated while minimizing interface reactions via the low-temperature heat treatment.

According to the embodiments, PMOS negative bias temperature instability (NBTI) characteristics of the semiconductor device may be improved.

According to the embodiments, characteristics of the semiconductor devices may be improved by applying the microwaves to the semiconductor to remove the unstable bonds between the atoms remaining at the interface, and using the atoms such as hydrogen (H), fluorine (F), or chlorine (Cl) to bond the atoms remaining at the interface.

### BRIEF DESCRIPTION OF DRAWINGS

FIG. 1 is a view illustrating a method for manufacturing a semiconductor device according to an embodiment.

FIG. 2 is a view illustrating a method for manufacturing a semiconductor device according to another embodiment.

FIG. 3 is a view illustrating electron mobility characteristics of a semiconductor device manufactured according to the embodiment in FIG. 2.

FIG. 4 is a view illustrating a method for manufacturing a semiconductor device according to another embodiment.

FIG. 5 is a view illustrating a method for manufacturing a semiconductor device according to another embodiment.

FIG. 6 is a view illustrating electron mobility characteristics of a semiconductor device manufactured according to the embodiment in FIG. 5.

### DETAILED DESCRIPTIONS

Hereinafter, embodiments of the present disclosure will be described in detail with reference to the attached drawings such that those skilled in the art may easily understand and reproduce them. In describing the present disclosure, when it is judged that a specific description of a related known function or component may unnecessarily obscure the gist of the embodiments of the present disclosure, the detailed description may be omitted. Because terms used herein may be sufficiently modified based on an intention of a user or an operator, custom, and the like, definition of each term should be made based on the contents throughout the present disclosure.

Moreover, aforementioned and additional aspects of the invention will become apparent with embodiments to be described below. The aspects or embodiments of the present disclosure that are optionally described, even though illustrated as a single integrated configuration in the drawings, should be understood to be freely combinable with one another unless otherwise stated or unless it is apparent to a person skilled in the art that such combinations are technically inconsistent.

Accordingly, the embodiments described in the present disclosure and the configurations illustrated in the drawings are merely preferred embodiments of the present disclosure and do not represent all of the technical ideas of the present disclosure. Therefore, it should be understood that there may be various equivalents and modifications that may replace them at the time of filing the present application.

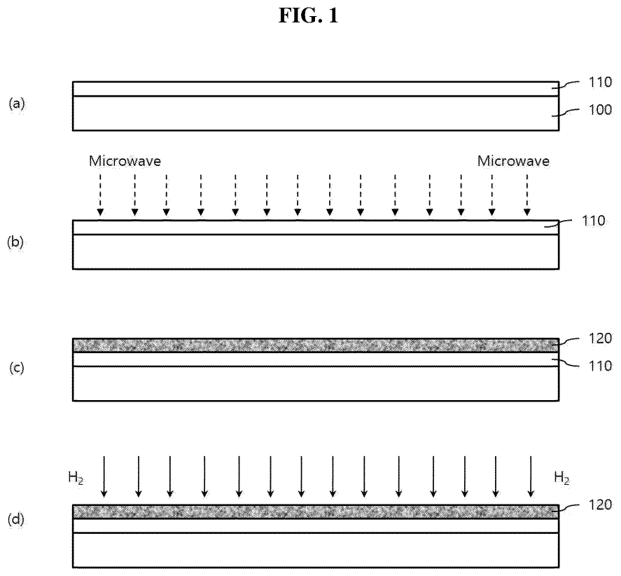

FIG. 1 is a view illustrating a method for manufacturing a semiconductor device according to an embodiment.

The method for manufacturing the semiconductor device according to an embodiment may include a step a of forming a first insulating layer 110 on a substrate 100, a step b of performing a first microwave (MW) heat treatment process, a step c of forming a conductive layer 120 on the first insulating layer, and a step d of performing a hydrogen heat treatment process.

The substrate 100 may include a silicon (Si) component. The first insulating layer 110 may include a silica (SiO₂) component. Generally, there are a certain density of silicon atoms on a surface of the substrate with the silicon (Si) component, and most of the silicon atoms bond with oxygen via a SiO₂ formation process. However, about 1% or less of these atoms may form dangling bonds, and electrical characteristics of the semiconductor device may deteriorate because of such weak bonds, i.e., defects.

In an embodiment, the step b of performing the first microwave (MW) heat treatment process may be performed in a frequency band range of 2.4 GHz to 2.5 GHz and a temperature range of 200° C. to 500° C. According to the embodiment, the step b of performing the first microwave (MW) heat treatment process may also be performed in a frequency band range of 1 GHz to 5 GHz. Preferably, the step b of performing the first microwave (MW) heat treatment process may be performed in a frequency band of 2.45 GHz and a temperature range of 250° C. to 450° C. for 0.5 minutes to 120 minutes.

The temperature conditions may be determined by a microwave (MW) intensity. The microwave (MW) heat treatment may have characteristics of a low thermal budget because a short heat treatment and selective heating are available. The microwave (MW) heat treatment promotes rotational and vibrational motions of the silicon atoms or the oxygen molecules, so that the defects caused by the formation of dangling bonds may be healed. In addition, the dangling bonds that are not healed by the microwave (MW) heat treatment may be changed into stable Si—H bonds by a hydrogen treatment process to be described below.

In an embodiment, the step c of forming the conductive layer 120 on the first insulating layer 110 may mean a metallization process. The conductive layer 120 may include a circuit pattern, an electrode, a source/drain, or a wiring. The conductive layer 120 may entirely or partially overlap the first insulating layer 110.

In an embodiment, the step d of performing the hydrogen (H₂) heat treatment process may be performed after the step c. The step d of performing the hydrogen (H₂) heat treatment process is preferably performed in a hydrogen atmosphere of 3% to 10%, in a pressure range of 2 atm to 50 atm and a temperature range of 200° C. to 500° C. (preferably 350° C. to 450° C.). Gas other than hydrogen may be nitrogen (N₂). When the hydrogen concentration is equal to or higher than 10%, a risk of explosion in a flammable environment may increase. However, use of the hydrogen concentration equal to or higher than 10% is not excluded, as it may be employed when design of a hydrogen heat treatment apparatus allows the same. For example, the step d of performing the hydrogen (H₂) heat treatment process may be performed in a hydrogen atmosphere of 90% to 100%.

Such process allows passivation of interface charges and fixed charges without damaging the conductive layer 120, at a relatively low temperature. This reduces densities of the interface charges and the fixed charges, thereby ensuring excellent electron mobility characteristics. Hydrogen may include deuterium (D₂).

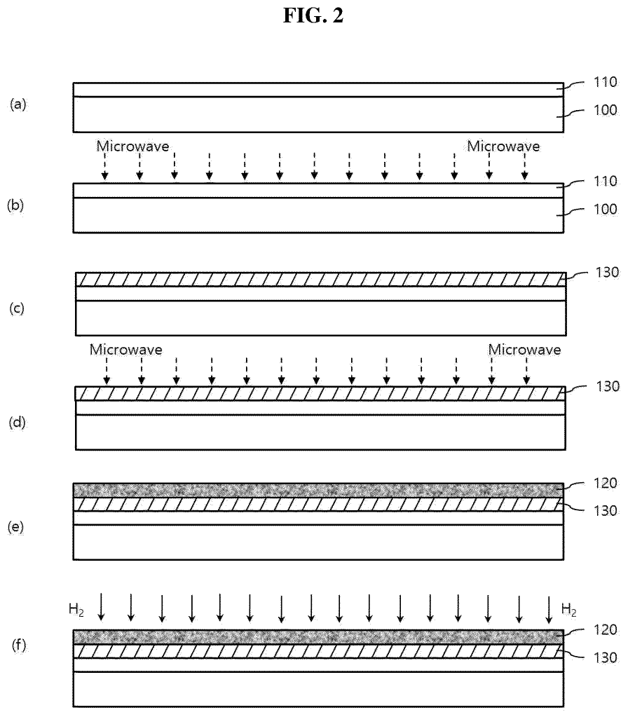

FIG. 2 is a view illustrating a method for manufacturing a semiconductor device according to another embodiment.

The method for manufacturing the semiconductor device by the heat treatment according to another embodiment may include a step a of forming the first insulating layer 110 on the substrate, a step b of performing the first microwave (MW) heat treatment process, a step c of forming a second insulating layer 130 having a permittivity higher than that of the first insulating layer on the first insulating layer, a step d of performing a second microwave heat treatment process, a step e of forming the conductive layer 120 on the second insulating layer, and a step f of performing the hydrogen (H₂) heat treatment process.

The substrate 100 may include the silicon (Si) component. The first insulating layer 110 may include the silica (SiO₂) component. Generally, there are the certain density of silicon atoms on the surface of the substrate with the silicon (Si) component, and most of the silicon atoms bond with oxygen via the SiO₂ formation process. However, about 1% or less of these atoms may form the dangling bonds, and the electrical characteristics of the semiconductor device may deteriorate because of such weak bonds, i.e., the defects.

In an embodiment, the step b of performing the first microwave (MW) heat treatment process may be performed in the frequency band range of 2.4 GHz to 2.5 GHZ and the temperature range of 200° C. to 500° C. According to the embodiment, the step b of performing the first microwave (MW) heat treatment process may also be performed in the frequency band range of 1 GHz to 5 GHz. Preferably, the step b of performing the first microwave (MW) heat treatment process may be performed in the frequency band of 2.45 GHz and the temperature range of 250° C. to 450° C. for 0.5 minutes to 120 minutes.

The temperature conditions may be determined by the microwave (MW) intensity. The microwave (MW) heat treatment may have the characteristics of the low thermal budget because the short heat treatment and the selective heating are available. The microwave (MW) heat treatment promotes the rotational and vibrational motions of the silicon atoms or the oxygen molecules, so that the defects caused by the formation of the dangling bonds may be healed. In addition, the dangling bonds that are not healed by the microwave (MW) heat treatment may be changed into the stable Si—H bonds by the hydrogen treatment process to be described below.

In the step c of forming the second insulating layer 130 having the permittivity higher than that of the first insulating layer on the first insulating layer 110, the permittivity of the second insulating layer may be higher than the permittivity of the first insulating layer. For example, the second insulating layer 130 may include at least one component among HfO₂, HfSiₓ, HfAlₓ, and HfSiO. Preferably, the second insulating layer 130 may include a component of hafnium oxide (HfO₂).

The step d of performing the second microwave (MW) heat treatment process may be performed in a frequency band range of 5.7 GHz to 5.9 GHz and a temperature range of 200° C. to 500° C. In another embodiment, the step d of performing the second microwave (MW) heat treatment process may also be performed in a frequency band range of 4 GHz to 7 GHz. The second insulating layer 130 may have a high ratio of dangling bonds because of characteristic of high dielectric constant (Hig-K). Therefore, a high frequency band may be applied. However, this is merely an embodiment. The step d of performing the second microwave (MW) heat treatment process may also be performed in a frequency band of 2.4 GHz to 2.5 GHz or a frequency band of 1 GHz to 5 GHz.

In an embodiment, the step e of forming the conductive layer 120 on the second insulating layer 130 may mean the metallization process. The conductive layer 120 may include the circuit pattern, the electrode, the source/drain, or the wiring. The conductive layer 120 may entirely or partially overlap the second insulating layer 130.

In another embodiment, a third insulating layer (not shown) may be formed between the conductive layer 120 and the second insulating layer 130.

In an embodiment, the step f of performing the hydrogen (H₂) heat treatment process may be performed after the step e. The step f of performing the hydrogen (H₂) heat treatment process is preferably performed in the hydrogen atmosphere of 3% to 10%, in the pressure range of 2 atm to 50 atm and the temperature range of 200° C. to 500° C. (preferably 350° C. to 450° C.). The gas other than hydrogen may be nitrogen (N₂). When the hydrogen concentration is equal to or higher than 10%, the risk of explosion in the flammable environment may increase. However, the use of the hydrogen concentration equal to or higher than 10% is not excluded, as it may be employed when the design of the hydrogen heat treatment apparatus allows the same. For example, the step f of performing the hydrogen (H₂) heat treatment process may be performed in the hydrogen atmosphere of 90% to 100%.

Such process allows the passivation of the interface charges and the fixed charges without damaging the conductive layer 120, at the relatively low temperature, so that the defects that are not healed by the microwave heat treatment may be passivated. This reduces the densities of the interface charges and the fixed charges, thereby ensuring the excellent electron mobility characteristics. Hydrogen may include deuterium (D₂).

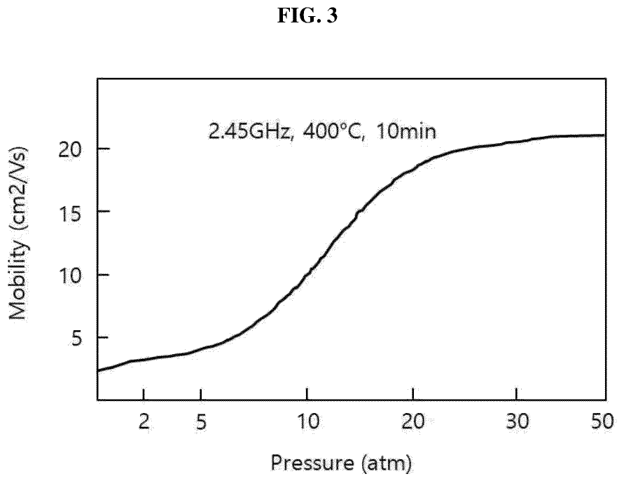

FIG. 3 is a view illustrating electron mobility characteristics of a semiconductor device manufactured according to the embodiment in FIG. 2.

Referring to FIG. 3, as a result of measuring the electron mobility of the semiconductor device, which was heat-treated at the microwave frequency band of 2.45 GHz, at a temperature of 400° C. while gradually increasing a hydrogen pressure for 10 minutes, the electron mobility was significantly increased in the pressure range of 2 atm to 50 atm.

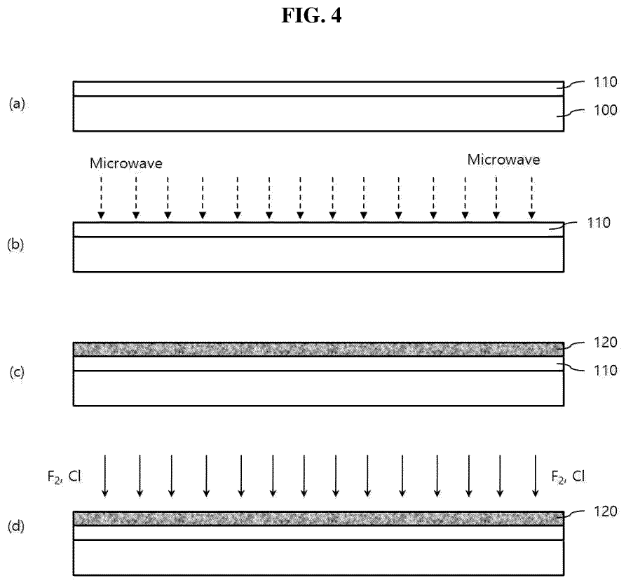

FIG. 4 is a view illustrating a method for manufacturing a semiconductor device according to another embodiment.

The method for manufacturing the semiconductor device by the heat treatment according to an embodiment may include a step a of forming the first insulating layer on the substrate, a step b of performing the first microwave heat treatment process, a step c of forming the conductive layer on the first insulating layer, and a step d of performing a fluorine (F₂) or chlorine (Cl) heat treatment process.

The substrate 100 may include the silicon (Si) component. The first insulating layer 110 may include the silica (SiO₂) component. Generally, there are the certain density of silicon atoms on the surface of the substrate with the silicon (Si) component, and most of the silicon atoms bond with oxygen via the SiO₂ formation process. However, about 1% or less of these atoms may form the dangling bonds, and the electrical characteristics of the semiconductor device may deteriorate because of such weak bonds, i.e., the defects.

In an embodiment, the step b of performing the first microwave (MW) heat treatment process may be performed in the frequency band range of 2.4 GHz to 2.5 GHz and the temperature range of 200° C. to 500° C. According to the embodiment, the step b of performing the first microwave (MW) heat treatment process may also be performed in the frequency band range of 1 GHz to 5 GHz. Preferably, the step b of performing the first microwave (MW) heat treatment process may be performed in the frequency band of 2.45 GHz and the temperature range of 250° C. to 450° C. for 0.5 minutes to 120 minutes.

The temperature conditions may be determined by the microwave (MW) intensity. The microwave (MW) heat treatment may have the characteristics of the low thermal budget because the short heat treatment and the selective heating are available. The microwave (MW) heat treatment promotes the rotational and vibrational motions of the silicon atoms or the oxygen molecules, so that the defects caused by the formation of the dangling bonds may be healed. In addition, the dangling bonds that are not healed by the microwave (MW) heat treatment may be changed into the stable Si—H bonds or Si—Cl bonds during the fluorine (F₂) or chlorine (Cl) heat treatment process to be described below.

The step c of forming the conductive layer 120 on the first insulating layer 110 according to an embodiment may mean the metallization process. The conductive layer 120 may include the circuit pattern, the electrode, the source/drain, or the wiring. The conductive layer 120 may entirely or partially overlap the first insulating layer 110.

The step d of performing the fluorine (F₂) or chlorine (Cl) heat treatment process according to an embodiment may be performed after the step c. the step d of performing the fluorine (F₂) or chlorine (Cl) heat treatment process may be performed in a concentration range of 0.1% to 1% and a temperature range of 300° C. to 500° C. for 10 to 30 minutes. Gas accounting for 99.9% to 99% other than fluorine (F₂) or chlorine (Cl) may be inert gas (e.g., argon (Ar)). Fluorine (F₂) gas may not necessarily have to be used, and other gases containing fluorine (F) may be used depending on the embodiment.

Depending on the embodiment, the concentration of fluorine (F₂) or chlorine (Cl) may be equal to or higher than 1%. For example, in the step d of performing the fluorine (F₂) or chlorine (Cl) heat treatment process, the concentration of fluorine (F₂) or chlorine (Cl) may be 90% to 100%.

In general, fluorine (F₂) and chlorine (Cl) have high reactivity characteristics. The fluorine (F₂) or chlorine (Cl) heat treatment process allows the passivation of the interface charges and the fixed charges without damaging the conductive layer 120, at the relatively low temperature. This reduces the densities of the interface charges and the fixed charges, thereby securing the excellent electron mobility characteristics and manufacturing a high-reliability element.

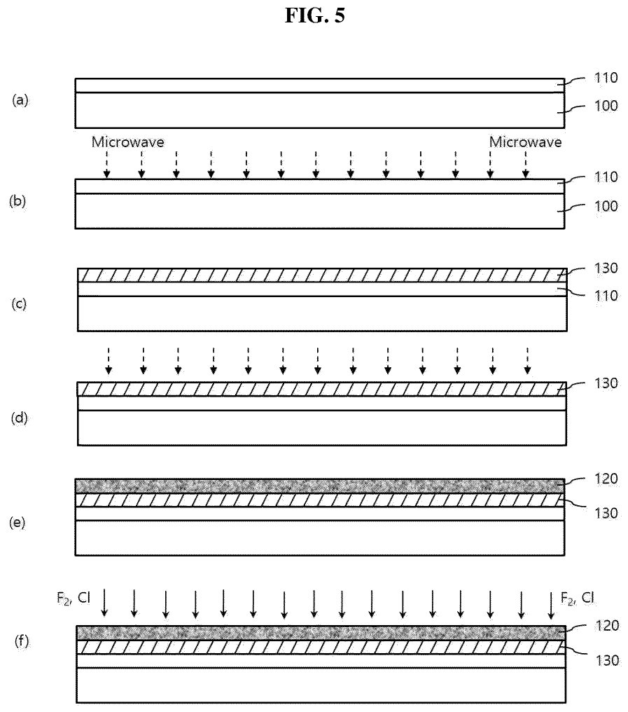

FIG. 5 is a view illustrating a method for manufacturing a semiconductor device according to another embodiment.

The method for manufacturing the semiconductor device by the heat treatment according to an embodiment may include a step a of forming the first insulating layer 110 on the substrate 100, a step b of performing the first microwave (MW) heat treatment process, a step c of forming the second insulating layer 130 having the permittivity higher than that of the first insulating layer on the first insulating layer 110, a step d of performing the second microwave (MW) heat treatment process, a step e of forming the conductive layer 120 on the second insulating layer 130, and a step f of performing the fluorine (F₂) or chlorine (Cl) heat treatment process.

The substrate 100 may include the silicon (Si) component. The first insulating layer 110 may include the silica (SiO₂) component. Generally, there are the certain density of silicon atoms on the surface of the substrate with the silicon (Si) component, and most of the silicon atoms bond with oxygen via the SiO₂ formation process. However, about 1% or less of these atoms may form the dangling bonds, and the electrical characteristics of the semiconductor device may deteriorate because of such weak bonds, i.e., the defects.

In an embodiment, the step b of performing the first microwave (MW) heat treatment process may be performed in the frequency band range of 2.4 GHz to 2.5 GHz and the temperature range of 200° C. to 500° C. According to the embodiment, the step b of performing the first microwave (MW) heat treatment process may also be performed in the frequency band range of 1 GHz to 5 GHz. Preferably, the step b of performing the first microwave (MW) heat treatment process may be performed in the frequency band of 2.45 GHz and the temperature range of 250° C. to 450° C. for 0.5 minutes to 120 minutes.

The temperature conditions may be determined by the microwave (MW) intensity. The microwave (MW) heat treatment may have the characteristics of the low thermal budget because the short heat treatment and the selective heating are available. The microwave (MW) heat treatment promotes the rotational and vibrational motions of the silicon atoms or the oxygen molecules, so that the defects caused by the formation of the dangling bonds may be healed. In addition, the dangling bonds that are not healed by the microwave (MW) heat treatment may be changed into the stable Si—H bonds or Si—Cl bonds during the fluorine (F₂) or chlorine (Cl) heat treatment process to be described below.

In the step c of forming the second insulating layer 130 having the permittivity higher than that of the first insulating layer on the first insulating layer 110, the permittivity of the second insulating layer may be higher than the permittivity of the first insulating layer. For example, the second insulating layer 130 may include at least one component among HfO₂, HfSiₓ, HfAlₓ, and HfSiO. Preferably, the second insulating layer 130 may include the component of hafnium oxide (HfO₂).

The step d of performing the second microwave (MW) heat treatment process may be performed in the frequency band range of 5.7 GHz to 5.9 GHz and the temperature range of 200° C. to 500° C. The step d of performing the second microwave (MW) heat treatment process may also be performed in the frequency band range of 4 GHz to 7 GHz. The second insulating layer 130 may have the high ratio of dangling bonds because of the characteristic of the high dielectric constant (High-K). Therefore, the high frequency band may be applied. However, this is merely an embodiment. The step d of performing the second microwave (MW) heat treatment process may also be performed in the frequency band of 2.4 GHz to 2.5 GHz or the frequency band of 1 GHz to 5 GHz.

The step e of forming the conductive layer 120 on the second insulating layer 130 according to an embodiment may mean the metallization process. The conductive layer 120 may include the circuit pattern, the electrode, the source/drain, or the wiring. The conductive layer 120 may entirely or partially overlap the first insulating layer 110.

The step f of performing the fluorine (F₂) or chlorine (Cl) heat treatment process according to an embodiment may be performed after the step e. The step f of performing the fluorine (F₂) or chlorine (Cl) heat treatment process may be performed in the concentration range of 0.1% to 1% and the temperature range of 300° C. to 500° C. for 10 to 30 minutes. Gas accounting for 99.9% to 99% other than fluorine (F₂) or chlorine (Cl) may be inert gas (e.g., argon (Ar)). Fluorine (F₂) gas may not necessarily have to be used, and other gases containing fluorine (F) may be used depending on the embodiment.

Depending on the embodiment, the concentration of fluorine (F₂) or chlorine (Cl) may be equal to or higher than 1%. For example, in the step f of performing the fluorine (F₂) or chlorine (Cl) heat treatment process, the concentration of fluorine (F₂) or chlorine (Cl) may be 90% to 100%.

Such fluorine (F₂) or chlorine (Cl) heat treatment process allows the passivation of the interface charges and the fixed charges without damaging the conductive layer 120, at the relatively low temperature. As a result, the defects that are not healed by the microwave heat treatment may be passivated. Further, this reduces the densities of the interface charges and the fixed charges, thereby securing the excellent electron mobility characteristics and manufacturing the high-reliability element.

According to an embodiment, the step f of performing the hydrogen (H₂) heat treatment process in FIG. 2 may be further performed after the step f of performing the fluorine (F₂) or chlorine (Cl) heat treatment process. This may further enhance the passivation effect by the hydrogen heat treatment.

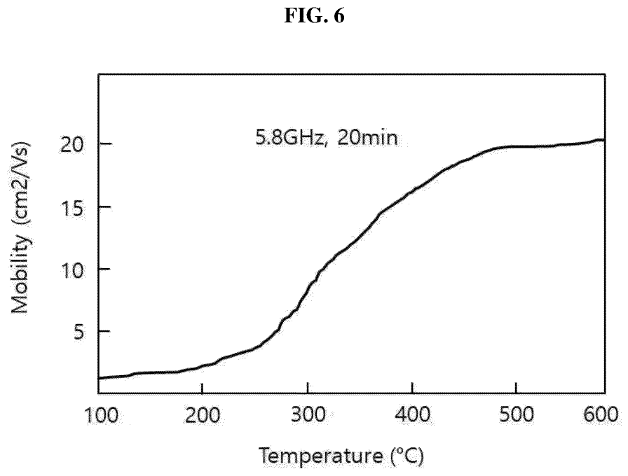

FIG. 6 is a view illustrating electron mobility characteristics of a semiconductor device manufactured according to the embodiment in FIG. 5.

Referring to FIG. 6, as a result of measuring the electron mobility of the semiconductor device, which was heat-treated at the microwave frequency band of 5.8 GHz, while gradually increasing a temperature of a fluorine (F₂) environment for 20 minutes, the electron mobility was significantly increased in the temperature range of 300° C. to 500° C.

Although the embodiments have been described with reference to the accompanying drawings as described above, the present disclosure is not limited to the embodiments disclosed in the present disclosure and the drawings, and various modifications may be made thereto by a person skilled in the art. In addition, although an effect according to a configuration of the present disclosure is not explicitly described in describing the embodiments of the present disclosure above, a predictable effect from the configuration should also be recognized.

What is claimed is:

1. A method for manufacturing a semiconductor device, the method comprising:
forming an insulating layer on a substrate;
performing a microwave heat treatment process;
forming a conductive layer on the insulating layer; and
performing a heat treatment process.

2. The method of claim 1, wherein the insulating layer includes a silica (SiO₂) component.

3. The method of claim 1, wherein the performing of the microwave heat treatment process is performed in a temperature range of 200° C. to 500° C.

4. The method of claim 1, wherein the heat treatment process is performed in a gaseous atmosphere including at least one of hydrogen, fluorine, and chlorine.

5. The method of claim 4, wherein the heat treatment process is performed in a pressure range of 2 atm to 50 atm and a temperature range of 200° C. to 500° C.

6. A method for manufacturing a semiconductor device, the method comprising:
forming a first insulating layer on a substrate;
performing a first microwave heat treatment process;
forming a second insulating layer having a permittivity higher than a permittivity of the first insulating layer on the first insulating layer;
performing a second microwave heat treatment process;
forming a conductive layer on the second insulating layer; and
performing a heat treatment process.

7. The method of claim 6, wherein the first insulating layer includes a silica (SiO₂) component and the second insulating layer includes a hafnium oxide (HfO₂) component.

8. The method of claim 6, wherein the first microwave heat treatment process or the second microwave heat treatment process is performed in a temperature range of 200° C. to 500° C.

9. The method of claim 6, wherein the heat treatment process is performed in a gaseous atmosphere including at least one of hydrogen, fluorine, and chlorine.

10. The method of claim 9, wherein the heat treatment process is performed in a pressure range of 2 atm to 50 atm and a temperature range of 200° C. to 500° C.
